(19) United States
(12) Patent Application Publication
(10) Pub. No.: US 2026/0349043 A1
(43) Pub. Date: Nov. 5, 2026

(54) Apparatus and Method for Estimating Parameters of Equivalent Circuit Model for Battery

(71) Applicant: LG Energy Solution, Ltd., Seoul (KR)

(72) Inventor: Yong Chul Sung, Daejeon (KR)

(73) Assignee: LG Energy Solution, Ltd., Seoul (KR)

(21) Appl. No.: 19/485,861

(22) PCT Filed: Jan. 9, 2024
(86) PCT No.: PCT/KR2024/000428

§ 371 Date: Nov. 19, 2025

(30) Foreign Application Priority Data
May 22, 2023 (KR) 10-2023-0065644

(51) Int. Cl. G01R 31/3842; G01R 19/10; G01R 31/367; G01R 31/374; G01R 31/389

(52) U.S. Cl. CPC G01R 31/3842; G01R 19/10; G01R 31/367; G01R 31/374; G01R 31/389

(57) ABSTRACT

The parameter estimation apparatus may include an acquisition unit configured to acquire battery information comprising current, temperature, and state of charge of a battery unit, and a parameter estimation unit configured to estimate parameters of an equivalent circuit model for the battery unit based on the battery information, wherein the equivalent circuit model may include a first resistor, a second resistor connected in series with the first resistor, and a capacitor connected in parallel with the second resistor, and the parameter estimation unit may estimate the resistance of the first resistor among the parameters by inputting the current of the battery unit into an equation comprising at least one predetermined value corresponding to the temperature and the state of charge, with the current as a variable.

### CROSS-REFERENCE TO RELATED APPLICATIONS

The present application is a national phase entry under 35 U.S.C. § 371 of International Application No. PCT/KR2024/000428, filed on Jan. 9, 2024, and published as International Publication No. WO 2024/242274A1, which claims priority from Korean Patent Application No. 10-2023-0065644, filed on May 22, 2023, all of which are hereby incorporated herein by reference.

### TECHNICAL FIELD

The embodiments disclosed in this document relate to an apparatus and method for estimating parameters of an equivalent circuit model for a battery.

### BACKGROUND

Recently, research and development on secondary batteries have been actively conducted. Here, the secondary battery is a rechargeable battery and includes all of the conventional Ni/Cd batteries, Ni/MH batteries, and recent lithium ion batteries. Among the secondary batteries, Lithium ion batteries have an advantage of much higher energy density than the conventional Ni/Cd batteries and Ni/MH batteries. In addition, Lithium-ion batteries can be manufactured small and lightweight enough to be used as power sources for mobile devices and recently expand their usage range to power sources for electric vehicles, drawing attention as a next-generation energy storage medium.

To prevent overcharging and overdischarging of the battery, it is necessary to adjust the charging current and discharging current of the battery according to the state of charge (SOC) of the battery. However, the SOC of the battery is not directly measurable, but is estimated based on the terminal voltage and current of the battery. Therefore, for safer and more efficient control of the battery, accurately estimating the state of charge is crucial.

Generally, the estimation of the SOC for batteries widely relies on the use of Extended Kalman Filter (EKF)-based methods, and the Extended Kalman Filter includes a battery voltage estimation process based on an equivalent circuit model.

To estimate the battery voltage using the equivalent circuit model, values known as battery parameters such as R0, R1, C1 are required. Since these battery parameters can vary with the battery's temperature and SOC, methods have been employed to estimate the battery parameters based on the battery's temperature and SOC.

### SUMMARY OF THE INVENTION

### Technical Problem

However, the internal resistance of an actual battery can vary with changes in the magnitude of the current. In particular, given the pronounced variations in resistance with changes in the magnitude of current at low temperatures, it is necessary to consider the influence of current when determining the internal resistance of the battery to improve the accuracy of battery state estimation.

The embodiments disclosed in this document may provide a parameter estimation apparatus and method capable of estimating the parameters of an equivalent circuit model for a battery in consideration of not only temperature and SOC information but also current information.

The technical objects of the embodiments disclosed in this document are not limited to the aforesaid, and other objects not described herein with be clearly understood by those skilled in the art from the descriptions below.

### Technical Solution

A parameter estimation apparatus according to an embodiment may include one or more sensors configured to acquire battery information comprising current, temperature, and state of charge of a battery unit, and a processor configured to estimate parameters of an equivalent circuit model for the battery unit based on the battery information, wherein the equivalent circuit model comprises a first resistor, a second resistor connected in series with the first resistor, and a capacitor connected in parallel with the second resistor, wherein the processors is configured to estimate the resistance of the first resistor by inputting the current of the battery unit into an equation, wherein the equation defines a relationship between the estimated resistance of the first resistor and the current of the battery unit according to at least one equation parameter that is based on the temperature and the state of charge of the acquired battery information.

In the parameter estimation apparatus according to an embodiment, the equation may include a first equation parameter and a second equation parameter, and the equation may be

Ro=a+b·log₁₀ (I)
in which Ro denotes the estimated resistance of the first resistor, a denotes the first equation parameter, b denotes the second equation parameter, and I denotes the current of the battery unit.

In the parameter estimation apparatus according to an embodiment the processor may be configured to correct at least one of the first equation parameter or the second equation parameter by comparing a measured resistance of the battery unit corresponding to the first resistor and the estimated resistance of the first resistor.

In the parameter estimation apparatus according to an embodiment the processor may be configured to estimate an open circuit voltage (OCV) of the equivalent circuit model based on the state of charge of the battery unit.

In the parameter estimation apparatus according to an embodiment disclosed in this document, the processor may be configured to estimate a direct current (DC) component voltage of the equivalent circuit model by multiplying the current of the battery unit and the estimated resistance of the first resistor.

In the parameter estimation apparatus according to an embodiment, the processor may be configured to estimate the resistance of the second resistor among the parameters based on the battery information, and estimate an alternating current (AC) component voltage of the equivalent circuit model based on the estimated resistance of the second resistor.

In the parameter estimation apparatus according to an embodiment, the processor may be configured to estimate a terminal voltage of the battery unit by summing up the OCV, the DC component voltage, and the AC component voltage.

A parameter estimation method according to an embodiment may include acquiring battery information including current, temperature, and state of charge of a battery unit, and estimating parameters of an equivalent circuit model for the battery unit based on the battery information, wherein the equivalent circuit model may include a first resistor, a second resistor connected in series with the first resistor, and a capacitor connected in parallel with the second resistor, and wherein estimating the parameters comprises estimating the resistance of the first resistor by inputting the current of the battery unit into an equation, wherein the equation defines a relationship between the estimated resistance of the first resistor and the current of the battery unit according to at least one equation parameter that is based on the temperature and the state of charge of the acquired battery information.

In the parameter estimation method according to an embodiment, the equation may include a first equation parameter and a second equation parameter, and the equation may be.

Ro=a+b·log₁₀ (I)

in which Ro denotes the estimated resistance of the first resistor, a denotes the first equation parameter, b denotes the second equation parameter, and I denotes the current of the battery unit.

The parameter estimation apparatus according to an embodiment may further include correcting at least one of the first equation parameter or the second equation parameter by comparing a measured resistance of the battery unit corresponding to the first resistor and the estimated resistance of the first resistor.

The parameter estimation apparatus according to an embodiment may further include estimating an open circuit voltage (OCV) of the equivalent circuit model based on the state of charge of the battery unit.

The parameter estimation apparatus according to an embodiment may further include estimating a direct current (DC) component voltage of the equivalent circuit model by multiplying the current of the battery unit and the estimated resistance of the first resistor.

In the parameter estimation method according to an embodiment, estimating the parameters further include estimating the resistance of the second resistor among the parameters based on the battery information, and estimating an alternating current (AC) component voltage of the equivalent circuit model based on the estimated resistance of the second resistor.

The parameter estimation apparatus according to an embodiment may further include estimating a terminal voltage of the battery unit by summing up the OCV, the DC component voltage, and the AC component voltage.

### Advantageous Effects

According to the embodiments disclosed in this document, it is possible to improve the accuracy of battery state estimation by additionally considering the influence of current on the resistance value of the DC component resistance included in the equivalent circuit model of the battery.

In addition, various effects identified directly or indirectly through this document can be provided.

### BRIEF DESCRIPTION OF THE DRAWINGS

FIG. 1 is a diagram illustrating an exemplary equivalent circuit model of a battery.

FIG. 2 is a graph illustrating an example of how internal resistance varies with the current of the battery.

FIG. 3 is a block diagram of a parameter estimation apparatus according to an embodiment;

FIG. 4 is a diagram illustrating graphs comparing the internal resistance measured by the parameter estimation apparatus according to an embodiment with the measured resistances for a battery;

FIG. 5 is a flowchart illustrating the operation of a parameter estimation apparatus according to an embodiment; and

FIG. 6 is a flowchart illustrating the operation of a parameter estimation apparatus according to an embodiment.

### DETAILED DESCRIPTION

Hereinafter, various embodiments of the present invention will be described with reference to the accompanying drawings. However, the description is not intended to limit the present invention to particular embodiments, and it should be construed as including various modifications, equivalents, and/or alternatives of the embodiments described herein.

Various embodiments disclosed in this document and terms used therein are not intended to limit the technical features described in this document to specific embodiments, and the disclosure should be construed as including various modifications, equivalents, and/or alternatives of the corresponding embodiments. In connection with the description of the drawings, like reference numbers may be used for like or related elements. The singular form of a noun corresponding to an item may include one item or a plurality of items unless the relevant context clearly dictates otherwise.

In this document, each of the phrases such as “A or B”, “at least one of A and B”, “at least one of A or B”, “A, B or C”, “at least one of A, B and C”, and “at least one of A, B, or C” may include any of the items listed together in the corresponding phrase or any possible combination thereof. Terms such as “the first”, “the second”, “first”, “second”, “A”, “B”, “(a)”, or “(b)” may be used simply to distinguish such components from other components and do not limit the corresponding components in other aspects (e.g., importance or order) unless otherwise stated specifically.

In this document, when it is mentioned that a (e.g., first) component is “connected”, “coupled”, “accessed”, with or without the terms “functionally” or “communicatively”, to another (e.g., second) component, it means that the component can be connected to the other component directly (e.g., wired), wirelessly, or via a third component. According to various embodiments, each component (e.g., module or program) of the components described above may include a single object or a plurality of objects, and some of the multiple objects may be separately disposed in other components.

According to various embodiments, one or more components or operations among the aforementioned components may be omitted, or one or more other components or operations may be added. Alternatively or additionally, a plurality of components (e.g., modules or programs) may be integrated into a single component. In this case, the integrated component may perform one or more functions of each of the plurality of components identically or similarly to those performed by the corresponding component of the plurality of components prior to the integration. According to various embodiments, operations performed by modules, programs, or other components are executed sequentially, in parallel, iteratively, or heuristically, or one or more of the operations are executed in a different order, omitted, or one or more other operations may be added.

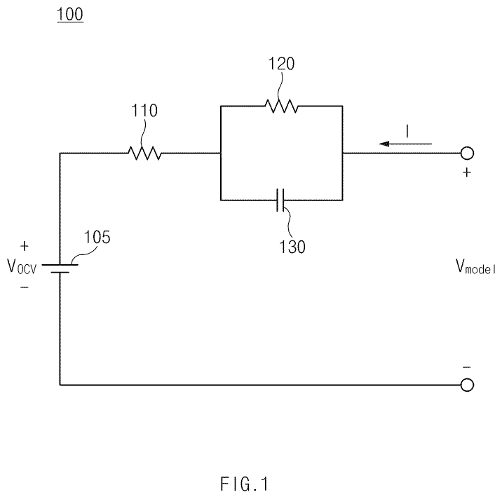

FIG. 1 is a diagram illustrating an exemplary equivalent circuit model of a battery.

With reference to FIG. 1, the equivalent circuit model 100 may include a voltage source 105, a first resistor 210, a second resistor 120, and a capacitor 130. The parameters of the equivalent circuit model 100 may include the resistance Ro of the first resistor 110, the resistance R₁ of the second resistor 120, and the capacitance C of the capacitor 130.

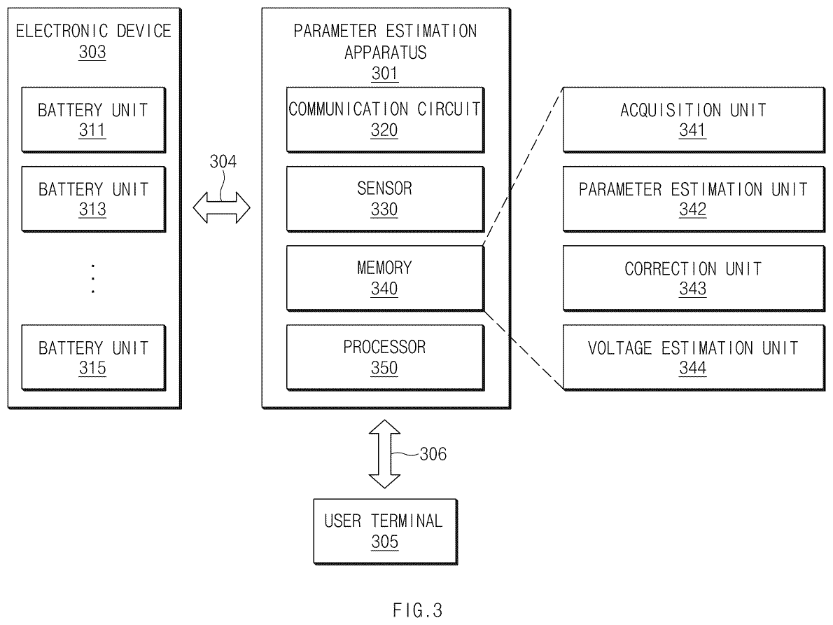

The voltage source 105 represents the open-circuit voltage V_{OCV} of the battery, determined by the state of charge (SOC) and temperature of the battery. That is, the open-circuit voltage V_{OCV} may be uniquely determined when the SOC and temperature are specified. The open-circuit voltage V_{OCV} may be predefined for each SOC and temperature. That is, an OCV-SOC map defining the correlation between the SOC and temperature of the battery and open-circuit voltage (V_{OCV}) may be prestored in the memory 340 to be described later with reference to FIG. 3.

The first resistor 210 simulates short-term voltage fluctuations caused by the current flowing through the battery.

The second resistor 120 and capacitor 130 are connected in parallel to each other. As shown in the drawing, the second resistor 120 may be connected in series with the first resistor 110. The parallel connection circuit of the second resistor 120 and capacitor 130 may be referred to as an ‘RC pair.’ Unlike the first resistor 110, the second resistor 120 is connected in parallel to the capacitor 130. Therefore, the RC pair may simulate the polarization voltage generated during charging and discharging of the battery. That is, the parallel combination of the second resistor 120 and capacitor 130 is designed to simulate the excessive response of the battery.

The terminal voltage V_{model} of the equivalent circuit model 100 may be calculated by summing the open-circuit voltage V_{OCV}, the voltage across the first resistor 110 (Vo), and the voltage across the second resistor 120 (V₁). Here, the voltage across the first resistor (Vo) is calculated by multiplying the current I flowing through the first resistor 110 by the resistance Ro, and the voltage across the second resistor V₁ is calculated by multiplying the current flowing through the second resistor 120 by the resistance R₁.

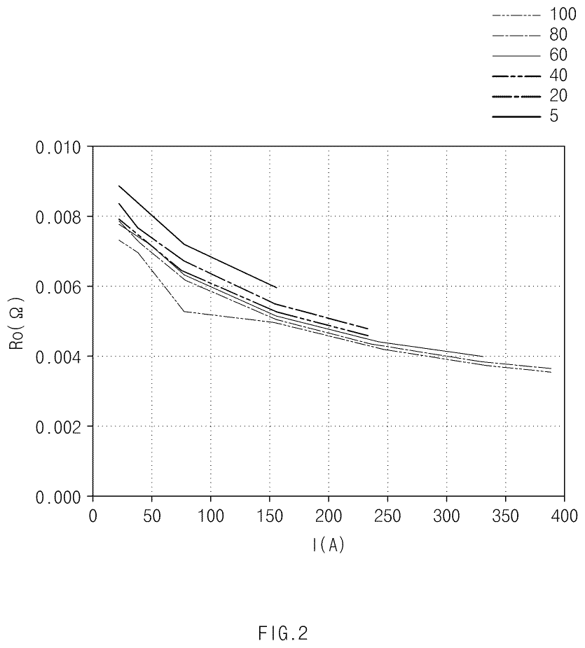

FIG. 2 is a graph illustrating an example of how internal resistance varies with the current of the battery. The graph in FIG. 2 may represent the internal resistance of the battery as a function of current under predetermined temperature conditions (e.g., −20 °C) and predetermined SOC conditions (e.g., 100%, 80%, 60%, 40%, 20%, or 5%).

With reference to FIG. 2, it can be observed that the internal resistance Ro of the battery varies with the current I. In particular, the graph in FIG. 2 illustrates the variation in the internal resistance Ro of the battery under low-temperature conditions (e.g., −20 °C), confirming a significant change in the internal resistance Ro with variations in the magnitude of current I at low temperatures. Therefore, it is necessary to consider the influence of current when determining the internal resistance of the battery equivalent circuit model.

FIG. 3 is a block diagram of a parameter estimation apparatus according to an embodiment.

With reference to FIG. 3, the parameter estimation apparatus 301 may be connected to an electronic device 303 and a user terminal 305 through a wired and/or wireless connection.

The operation of the parameter estimation apparatus 301 described below may be performed not only by a battery management system (BMS) in the vehicle but also by various devices such as servers, clouds, chargers, or charging-discharging equipment.

According to an embodiment, the connection 304 between the parameter estimation apparatus 301 and the electronic device 303 may be a communication link established through wired and/or wireless networks. In an embodiment, the wired network may be based on local area network (LAN) or power line communication. In an embodiment, the wireless network may be based on a short range communication network (e.g., Bluetooth, wireless fidelity (Wi-Fi), infrared data association (IrDA)) or a long-range communication network (e.g., cellular network encompassing 4G and 5G networks).

According to another embodiment, the connection 304 between the parameter estimation apparatus 301 and the electronic device 303 may be a connection established through an inter-device communication interface (e.g., bus, general purpose input and output (GPIO), serial peripheral interface (SPI), or mobile industry processor interface (MIPI)).

According to an embodiment, the connection 306 between the parameter estimation apparatus 301 and the user terminal 305 may be a communication link established through wired and/or wireless networks.

According to an embodiment, the electronic device 303 may be a mobile device (e.g., portable phone, laptop computer, smartphone, and smart pad), an electrified vehicle (e.g., electric vehicle (EV), hybrid EV (HEV), plug-in HEV (PHEV), and fuel cell EV (FCEV), an energy storage system (ESS), or a battery swapping system (BSS).

According to an embodiment, the electronic device 303 may include one or more battery units 311, 313, and 315. Each of the one or more battery units 311, 313, and 315 may be a battery cell, battery module, battery pack, or battery rack.

According to an embodiment, the user terminal 305 may be a mobile device (e.g., portable phone, laptop computer, smartphone, and smart pad) or a personal computer (PC). According to an embodiment, the parameter estimation apparatus 301 may provide information about the estimation results to the user terminal.

According to an embodiment, the parameter estimation apparatus 301 may include a communication circuit 320, a sensor 330, a memory 340, and a processor 350. According to an embodiment, the parameter estimation apparatus 301 shown in FIG. 3 may further include at least one additional component (e.g., a display, input device, or output device) other than the components illustrated in FIG. 3.

In an embodiment, the communication circuit 320 may establish a wired and/or wireless communication channel between the parameter estimation apparatus 301 and the electronic device 303 and/or user terminal 305 and exchange data with the electronic device 303 and/or the user terminal 305 through the established communication channel.

According to an embodiment, the sensor 330 may acquire values related to the state of the battery units 111, 113, and 115 of the electronic device 303. In an embodiment, the values related to the state may include one or more values representing the voltage, current, resistance, state of charge (SOC), state of health (SOH), or temperature of the battery units 111, 113, and 115, or any combination thereof. In the following, a value related to a state may be referred to as a state value.

According to an embodiment, the memory 340 may include volatile memory and/or non-volatile memory.

According to an embodiment, the memory 340 may store data used by at least one component of the parameter estimation apparatus 301 (e.g., processor 350). For example, the data may include software (or related instructions), input data, or output data. In an embodiment, the instructions may be executed by the processor 350 for the battery abnormality diagnosis apparatus 101 to perform operations defined by the instructions.

According to an embodiment, the memory 340 may include one or more software components (e.g., acquisition unit 341, parameter estimation unit 342, correction unit 343, and voltage estimation unit 344).

According to an embodiment, the processor 350 may include a central processing unit, an application processor, a graphic processing unit, a neural processing unit (NPU), an image signal processor, a sensor hub processor, or a communication processor.

According to an embodiment, the processor 350 may execute software (e.g., acquisition unit 341, parameter estimation unit 342, correction unit 343, and voltage estimation unit 344) to control at least one other component (e.g., hardware or software component) connected to the processor 350 in the parameter estimation apparatus 301 and perform various data processing or operations.

Hereinafter, a description is made of the method for the parameter estimation apparatus 301 to estimate parameters and/or voltage of an equivalent circuit model for a battery units 311, 313, or 315 through the acquisition unit 341, parameter estimation unit 342, correction unit 343, and voltage estimation unit 344.

According to an embodiment, the acquisition unit 341 may acquire battery information, including the current, temperature, and SOC of the battery units 311, 313, or 315. For example, the acquisition unit 341 may acquire the battery information from the electronic device 303 and/or an external server connected via wired and/or wireless networks using the communication circuit 320. As another example, the acquisition unit 341 may obtain the battery information by measuring the voltage, current, and/or temperature of the battery units 311, 313, or 315 through the sensor 330 and estimating the SOC based on the measured voltage, current, and/or temperature.

According to an embodiment, the parameter estimation unit 342 may estimate the parameters of an equivalent circuit model for the battery units 311, 313, or 315 based on the battery information acquired by the acquisition unit 341.

Hereinafter, for the convenience of explanation, the description is made under the assumption that the parameter estimation apparatus 301 estimates the parameters of the first-order RC equivalent circuit model 100 composed of the components (e.g., voltage source 105, first resistor 110, second resistor 120, and capacitor 130) as shown in FIG. 1. Here, the parameters may include the resistance Ro of the first resistor 110, the resistance R₁ of the second resistor 120, and the capacitance C of the capacitor 130. However, the subsequent explanation does not limit the parameter estimation apparatus 301 to estimating only the parameters of the first-order RC equivalent circuit model. That is, the parameter estimation apparatus 301 may be configured to estimate the parameters of second-order or higher RC equivalent circuit models.

According to an embodiment, the parameter estimation unit 342 may estimate the resistance Ro of the first resistor 110 among the parameters by inputting the current of the battery unit 311, 313, or 315 into a predetermined equation. According to an embodiment, the predetermined equation may include at least one equation parameter corresponding to the temperature and SOC of the battery units 311, 313, or 315 and may be an equation with the current as a variable, meaning that the equation defines a relationship between the estimated resistance of the first resistor and the current of the battery unit. For example, the predetermined equation may be Equation 1.

Ro=a+b·log₁₀ [Equation 1]

In Equation 1, Ro may denote the resistance of the first resistor 110, a may denote a first equation parameter included among the at least one equation parameters, b may denote a second equation parameter included among the at least one equation parameters, and I may denote the current of the battery unit 311, 313, or 315.

According to an embodiment, at least one equation parameter (e.g., the first equation parameter a and/or the second equation parameter b) may be uniquely determined when the temperature and SOC of the battery unit 311, 313, or 315, which are parameters to be estimated, are determined. That is, a table defining the correlation between the temperature, SOC, and at least one equation parameter for the battery unit 311, 313, or 315 may be prestored in the memory 340.

According to an embodiment, the correction unit 343 may correct at least one of the first equation parameter a or the second equation parameter b. According to an embodiment, the correction unit 343 may compare the measured resistance of the first resistor 110 with the estimated resistance Ro of the first resistor 110 obtained by the parameter estimation unit 342. The correction unit 343 may correct at least one of the first equation parameter a or the second equation parameter b based on the comparison results. For example, the correction unit 343 may correct at least one of the first equation parameter a or the second equation parameter b to minimize the difference between the measured resistance and the estimated resistance Ro.

According to an embodiment, the parameter estimation apparatus 301 may update the first equation parameter a and/or the second equation parameter b in the table defining the correlation between temperature, SOC, and at least one equation parameter with the value corrected by the correction unit 343 and store the updated table in the memory 340.

According to an embodiment, the voltage estimation unit 344 may estimate the voltage across at least one component of equivalent circuit model 100.

According to an embodiment, the voltage estimation unit 344 may estimate the open-circuit voltage (OCV) of the equivalent circuit model 100 based on the SOC of the battery unit 311, 313, or 315. For example, the voltage estimation unit 344 may refer to an OCV-SOC map prestored in the memory 340 to estimate the OCV as a voltage value corresponding to the SOC.

According to an embodiment, the voltage estimation unit 344 may estimate the DC component voltage of the equivalent circuit model 100. Here, the DC component voltage may refer to the voltage applied to the terminals of the first resistor 110. For example, the voltage estimation unit 344 may estimate the DC component voltage by multiplying the current flowing through the battery unit 311, 313, or 315 and the resistance Ro of the first resistor 110 estimated by the parameter estimation unit 342.

According to an embodiment, the voltage estimation unit 344 may estimate the AC component voltage of the equivalent circuit model 100. Here, the AC component voltage may refer to the voltage applied across the second resistor 120 and the capacitor 130. For example, the voltage estimation unit 344 may estimate the AC component voltage based on the resistance R₁ of the second resistor 120 estimated by the parameter estimation unit 342. In more detail, the voltage estimation unit 344 may estimate the AC component voltage by multiplying the current flowing through the second resistor 120 and the resistance R₁ of the second resistor 120 in the equivalent circuit model 100.

According to an embodiment, the voltage estimation unit 344 may estimate the terminal voltage of the battery unit 311, 313, or 315. According to an embodiment, the voltage estimation unit 344 may estimate the terminal voltage of the battery unit 311, 313, or 315 by summing the OCV, DC component voltage, and AC component voltage of the equivalent circuit model 100.

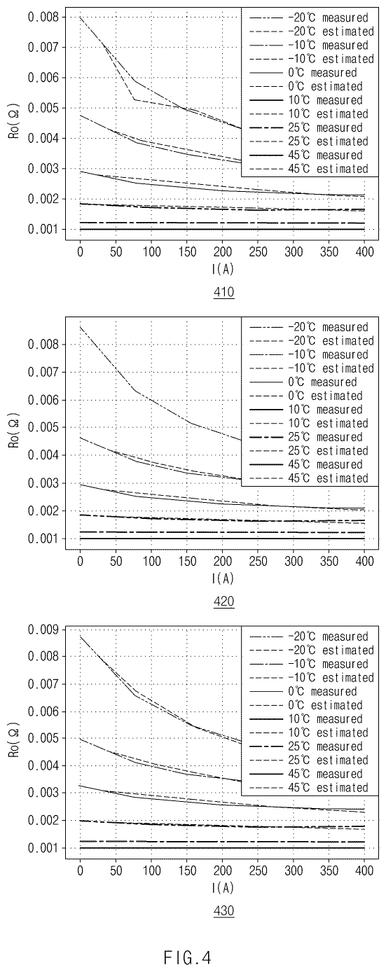

FIG. 4 is a diagram illustrating graphs comparing the internal resistance measured by the parameter estimation apparatus according to an embodiment with the measured resistances for a battery.

The graphs 410, 420, and 430 in FIG. 4 can represent the estimated internal resistance and measured internal resistance of the battery as a function of current under predetermined SOC conditions (e.g., graph 410 for 100%, graph 420 for 60%, and graph 430 for 20%) and predetermined temperatures (e.g., −20 °C, −10 °C, 0 °C, 10 °C, 25 °C, or 45 °C).

With reference to FIG. 4, it can be observed that the estimated internal resistance and measured internal resistance, determined by the parameter estimation apparatus 301, exhibit similar trends for each condition on the respective graphs 410, 420, or 430. That is, it can be confirmed that the battery internal resistance estimated by the parameter estimation unit 342 using Equation 1 exhibits similarity to the actual battery internal resistance.

FIG. 5 is a flowchart illustrating the operation of a parameter estimation apparatus according to an embodiment. FIG. 5 may illustrate the operations of the parameter estimation apparatus 301 of FIG. 3, and descriptions may be made on the basis of the configuration (e.g., parameter estimation apparatus 301) in FIG. 3.

The embodiment shown in FIG. 5 is merely one embodiment, and the order of operations according to various embodiments of the present invention may be different from that shown in FIG. 5, and some operations shown in FIG. 5 may be omitted, changed in order, or merged. For example, operation 515 may be omitted in FIG. 5.

With reference to FIG. 5, the parameter estimation apparatus 301 may acquire battery information, including the current, temperature, and SOC of the battery units 311, 313, or 315 in operation 505. For example, the parameter estimation apparatus 301 may acquire the battery information from the external electronic device 303 and/or an external server connected via wired and/or wireless networks using the communication circuit 320. As another example, the parameter estimation apparatus 301 may obtain the battery information by measuring the voltage, current, and/or temperature of the battery units 311, 313, or 315 through the 330 and estimating the SOC based on the measured voltage, current, and/or temperature.

In operation 510, the parameter estimation apparatus 301 may estimate the parameters of an equivalent circuit model for the battery units 311, 313, or 315 based on the battery information acquired in operation 505.

According to an embodiment, the parameter estimation apparatus 301 may estimate the resistance Ro of the first resistor 110 among the parameters by inputting the current of the battery units 311, 313, or 315 into a predetermined equation. According to an embodiment, the predetermined equation may include at least one equation parameter corresponding to the temperature and SOC of the battery units 311, 313, or 315 and may be an equation with the current as a variable. For example, the predetermined equation may be Equation 1.

According to an embodiment, the at least one equation parameter (e.g., the first equation parameter a and/or the second equation parameter b) may be uniquely determined when the temperature and SOC of the target battery unit 311, 313, or 315 is determined. That is, a table defining the correlation between the temperature, SOC, and at least one equation parameter for the battery unit 311, 313, or 315 may be prestored in the memory 340.

In operation 515, the parameter estimation apparatus 301 may adjust at least one equation parameter (e.g., at least one of the first equation parameter a or the second equation parameter b). According to an embodiment, the parameter estimation apparatus 301 may compare the measured resistance of the first resistor 110 with the estimated resistance Ro of the first resistor 110 obtained by the parameter estimation unit 342. The parameter estimation apparatus 301 may correct at least one of the first equation parameter a or the second equation parameter b based on the comparison results. For example, the parameter estimation apparatus 301 may correct at least one of the first equation parameter a or the second equation parameter b to minimize the difference between the measured resistance and the estimated resistance Ro.

According to an embodiment, the parameter estimation apparatus 301 may update the first equation parameter a and/or the second equation parameter b in the table defining the correlation between temperature, SOC, and at least one equation parameter with the value corrected by the correction unit 343 and store the updated table in the memory 340.

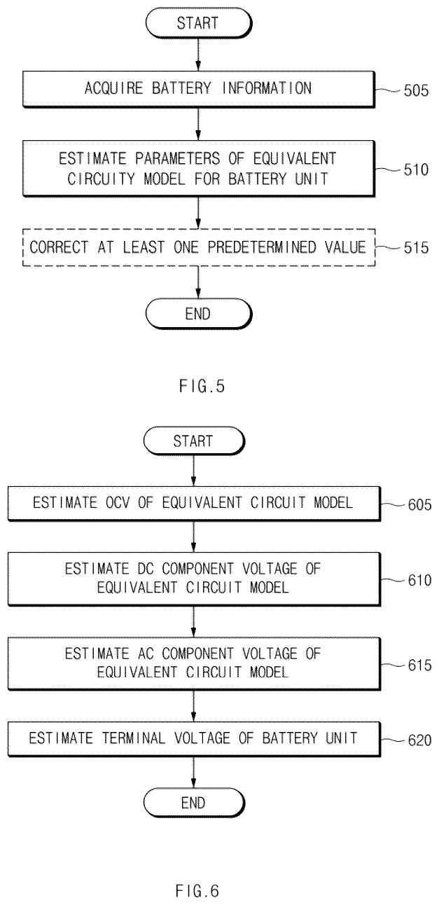

FIG. 6 is a flowchart illustrating the operation of a parameter estimation apparatus according to an embodiment. FIG. 6 may illustrate the operations of the parameter estimation apparatus 301 of FIG. 3, and descriptions may be made on the basis of the configuration (e.g., data processing apparatus 301) in FIG. 3.

The embodiment shown in FIG. 6 is merely one embodiment, and the order of operations according to various embodiments of the present invention may be different from that shown in FIG. 6, and some operations shown in FIG. 6 may be omitted, changed in order, or merged.

With reference to FIG. 6, the parameter estimation apparatus 301 may estimate the open-circuit voltage (OCV) of the equivalent circuit model 100 based on the SOC of the battery unit 311, 313, or 315 in operation 605. For example, the parameter estimation apparatus 301 may refer to an OCV-SOC map prestored in the memory 340 to estimate the OCV as a voltage value corresponding to the SOC.

In operation 610, the parameter estimation apparatus 301 may estimate the DC component voltage of the equivalent circuit model 100. Here, the DC component voltage may refer to the voltage applied to the terminals of the first resistor 110. For example, the parameter estimation apparatus 301 may estimate the DC component voltage by multiplying the current flowing through the battery unit 311, 313, or 315 and the estimate resistance Ro of the first resistor 110 estimated in operation 510.

In operation 615, the parameter estimation apparatus 301 may estimate the AC component voltage of the equivalent circuit model 100. Here, the AC component voltage may refer to the voltage applied across the second resistor 120 and the capacitor 130. For example, the voltage estimation apparatus 301 may estimate the AC component voltage based on the resistance R₁ of the second resistor 120 estimated in operation 510 of FIG. 5. In more detail, the parameter estimation apparatus 301 may estimate the AC component voltage by multiplying the current value flowing through the second resistor 120 and the resistance R₁ of the second resistor 120 in the equivalent circuit model 100.

In operation 620, the parameter estimation apparatus 301 may estimate the terminal voltage of the battery unit 311, 313, or 315. According to an embodiment, the parameter estimation apparatus 301 may estimate the terminal voltage of the battery unit 311, 313, or 315 by summing the OCV estimated in operation 605, the DC component voltage estimated in operation 610, and the AC component voltage estimated in operation 615.

Also, the terms such as “comprise”, “include”, or “have” used above implies that the corresponding component may be present unless otherwise stated specifically, and thus it should be construed as being able to further include other components rather than exclude other components. Unless otherwise defined herein, all terms including technical or scientific terms used herein have the same meanings as commonly understood by those skilled in the art to which the present invention belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

1. A parameter estimation apparatus comprising:
one or more sensors configured to acquire battery information comprising current, temperature, and state of charge of a battery unit; and
a processor configured to estimate parameters of an equivalent circuit model for the battery unit based on the battery information, wherein the equivalent circuit model comprises a first resistor, a second resistor connected in series with the first resistor, and a capacitor connected in parallel with the second resistor, wherein the processors is configured to estimate the resistance of the first resistor by inputting the current of the battery unit into an equation, wherein the equation defines a relationship between the estimated resistance of the first resistor and the current of the battery unit according to at least one equation parameter that is based on the temperature and the state of charge of the acquired battery information.

2. The parameter estimation apparatus of claim 1, wherein the equation includes a first equation parameter and a second equation parameter, and the equation is:
Ro=a+b·log₁₀ (I)
wherein Ro denotes the estimated resistance of the first resistor, a denotes the first equation parameter, b denotes the second equation parameter, and I denotes the current of the battery unit.

3. The parameter estimation apparatus of claim 2, wherein the processor is configured to correct at least one of the first equation parameter or the second equation parameter by comparing a measured resistance of the battery unit corresponding to the first resistor and the estimated resistance of the first resistor.

4. The parameter estimation apparatus of claim 1, wherein the processor is configured to estimate an open circuit voltage (OCV) of the equivalent circuit model based on the state of charge of the battery unit.

5. The parameter estimation apparatus of claim 4, wherein the processor is configured to estimate a direct current (DC) component voltage of the equivalent circuit model by multiplying the current of the battery unit and the estimated resistance of the first resistor.

6. The parameter estimation apparatus of claim 5, wherein the processor is configured to estimate the resistance of the second resistor among the parameters based on the battery information, and estimate an alternating current (AC) component voltage of the equivalent circuit model based on the estimated resistance of the second resistor.

7. The parameter estimation apparatus of claim 6, wherein the processor is configured to estimate a terminal voltage of the battery unit by summing up the OCV, the DC component voltage, and the AC component voltage.

8. A parameter estimation method comprising:
acquiring battery information comprising current, temperature, and state of charge of a battery unit; and
estimating parameters of an equivalent circuit model for the battery unit based on the battery information, wherein the equivalent circuit model comprises a first resistor, a second resistor connected in series with the first resistor, and a capacitor connected in parallel with the second resistor, and
wherein estimating the parameters comprises estimating the resistance of the first resistor by inputting the current of the battery unit into an equation, wherein the equation defines a relationship between the estimated resistance of the first resistor and the current of the battery unit according to at least one equation parameter that is based on the temperature and the state of charge of the acquired battery information.

9. The parameter estimation method of claim 8, wherein the equation includes a first equation parameter and a second equation parameter, and the equation is:
Ro=a+b·log₁₀ (I)
wherein Ro denotes the estimated resistance of the first resistor, a denotes the first equation parameter, b denotes the second equation parameter, and I denotes the current of the battery unit.

10. The parameter estimation method of claim 9, further comprising correcting at least one of the first equation parameter or the second equation parameter by comparing a measured resistance of the battery unit corresponding to the first resistor and the estimated resistance of the first resistor.

11. The parameter estimation method of claim 8, further comprising estimating an open circuit voltage (OCV) of the equivalent circuit model based on the state of charge of the battery unit.

12. The parameter estimation method of claim 11, further comprising estimating a direct current (DC) component voltage of the equivalent circuit model by multiplying the current of the battery unit and the estimated resistance of the first resistor.

13. The parameter estimation method of claim 12, wherein estimating the parameters further comprises:
estimating the resistance of the second resistor among the parameters based on the battery information; and
estimating an alternating current (AC) component voltage of the equivalent circuit model based on the estimated resistance of the second resistor.

14. The parameter estimation method of claim 13, further comprising estimating a terminal voltage of the battery unit by summing up the OCV, the DC component voltage, and the AC component voltage.
